(19) United States
(12) Patent Application Publication
(10) Pub. No.: US 2025/0016984 A1
(43) Pub. Date: Jan. 9, 2025

(54) SEMICONDUCTOR DEVICE AND FABRICATION METHOD THEREOF, MEMORY AND MEMORY SYSTEM

(71) Applicant: Yangtze Memory Technologies Co., Ltd., Wuhan (CN)

(72) Inventors: Xiaoxin LIU, Wuhan (CN); Zongliang HUO, Wuhan (CN)

(21) Appl. No.: 18/399,558

(22) Filed: Dec. 28, 2023

Related U.S. Application Data
(63) Continuation of application No. PCT/CN2023/106137, filed on Jul. 6, 2023.

(51) Int. Cl. H10B 12/00

(52) U.S. Cl. CPC H10B 12/33; H10B 12/05

(57) ABSTRACT

Semiconductor devices, fabrication methods thereof, memories and memory systems are provided. In one aspect, a semiconductor device includes: a semiconductor pillar array including a plurality of semiconductor pillars arranged in an array along a first direction and a second direction and extending in a third direction, a gate strip and a shielding strip disposed between adjacent ones of the semiconductor pillars along the second direction, and a barrier strip extending along the first direction. The gate strip and the shielding strip extend along the first direction and are spaced apart in the second direction. The first direction, the second direction and the third direction intersect with each other. The barrier strip is connected with an end of the shielding strip in the third direction, and is located on a same side of the shielding strip and the gate strip in the third direction.

### CROSS-REFERENCE TO RELATED APPLICATIONS

This application is a continuation of International Application No. PCT/CN2023/106137, filed on Jul. 6, 2023, the disclosure of which is hereby incorporated by reference in its entirety.

### TECHNICAL FIELD

The present application relates to the field of semiconductor technologies, and particularly to a semiconductor device and a fabrication method thereof, a memory and a memory system.

### BACKGROUND

As feature sizes of memory cells approach the lower limit of processes, planar processes and fabrication technologies become challenging and costly, which results in storage density of a memory of 2D structure approaching the upper limit.

In order to overcome the limitations brought about by the memory of 2D structure, the industry has developed a memory with three-dimensional structure to increase the storage density.

However, with increasing requirements for the integration level of memory, currently how to properly make an arrangement of various gates to reduce mutual interference between the gates is still a problem to be overcome.

### SUMMARY

The present application provides a semiconductor device and a fabrication method thereof, a memory and a memory system, which can increase yield and reliability of the memory.

In a first aspect, the present application provides a semiconductor device, comprising:
a semiconductor pillar array comprising a plurality of semiconductor pillars arranged in an array along a first direction and a second direction and extending in a third direction, wherein the first direction, the second direction and the third direction intersect with each other;
a gate strip and a shielding strip disposed between adjacent ones of the semiconductor pillars along the second direction, wherein the gate strip and the shielding strip extend along the first direction and are spaced apart in the second direction; and
a barrier strip extending along the first direction, wherein the barrier strip is connected with an end of the shielding strip in the third direction, and is located on the same side of the shielding strip and the gate strip in the third direction.

In a second aspect, the present application provides a fabrication method of a semiconductor device, which comprises:
forming a plurality of semiconductor pillars that are arranged in an array along a first direction and a second direction and extend in a third direction, wherein the first direction, the second direction and the third direction intersect with each other;
forming one gate strip and one shielding strip between a first row of the semiconductor pillars and a second row of the semiconductor pillars that are adjacent, wherein the gate strip and the shielding strip extend along the first direction and are spaced apart in the second direction; and
forming a barrier strip at an end of the shielding strip along the third direction, wherein the barrier strip extends along the first direction, and is located on the same side of the shielding strip and the gate strip in the third direction.

In a third aspect, the present application further provides a memory comprising:
an array memory structure comprising the semiconductor device of the first aspect; and
a periphery circuit connected with the array memory structure to control a bias voltage of the array memory structure.

In a fourth aspect, the present application further provides a memory system comprising: the memory of the third aspect; and a controller coupled with the memory, wherein the controller is configured to control the memory to perform data write and read operations.

The present application has the advantageous effects that: two electrodes, i.e., a first electrode and a second electrode, are formed between adjacent ones of the semiconductor pillars, and the barrier strip extending along the first direction and connected with the second electrode is formed at the same end of the first electrode and the second electrode in the third direction; as such, the first electrode can serve as the gate strip, and the second electrode can serve as the shielding strip; the shielding strip is formed at the same time as forming the gate strip, such that the interference between adjacent ones of the semiconductor pillars can be prevented by the shielding strip, thus reducing a coupling effect between adjacent ones of the semiconductor pillars.

### BRIEF DESCRIPTION OF THE DRAWINGS

The drawings to be used in description of examples will be briefly introduced below in order to illustrate the technical solutions in the examples of the present application more clearly. Apparently, the drawings described below are only some examples of the present application. Those skilled in the art may obtain other drawings according to these drawings without creative work.

FIG. 1 is an equivalent circuit diagram of one memory cell in a semiconductor device provided by examples of the present application;

FIG. 2 is a cross-sectional view of a semiconductor device provided by examples of the present application;

FIG. 3 is a top view of a substrate provided by examples of the present application;

FIG. 4 is a cross-sectional view of a substrate provided by examples of the present application;

FIG. 5 is a top view of forming isolation trenches provided by examples of the present application;

FIG. 6 is a cross-sectional view of forming isolation trenches along an AA′ cutting line in FIG. 5 provided by examples of the present application;

FIG. 7 is a top view of depositing a dielectric material in isolation trenches provided by examples of the present application;

FIG. 8 is a cross-sectional view of isolation trenches along a BB′ cutting line in FIG. 7 provided by examples of the present application;

FIG. 9 is a top view of forming gate trenches provided by examples of the present application;

FIG. 10 is a cross-sectional view of forming gate trenches along a CC′ cutting line in FIG. 9 provided by examples of the present application;

FIG. 11 is a top view of forming a first oxide layer at sidewalls of gate trenches provided by examples of the present application;

FIG. 12 is a cross-sectional view of forming a first oxide layer at sidewalls of gate trenches along a DD′ cutting line in FIG. 11 provided by examples of the present application;

FIG. 13 is a top view of forming a conductive layer on a first oxide layer provided by examples of the present application;

FIG. 14 is a cross-sectional view of forming a conductive layer on a first oxide layer along an EE′ cutting line in FIG. 13 provided by examples of the present application;

FIG. 15 is a cross-sectional view of a semiconductor device along an EE′ cutting line in FIG. 13 provided by examples of the present application;

FIG. 16 is a top view of filling an isolation material at inner walls of gate trenches provided by examples of the present application;

FIG. 17 is a cross-sectional view of filling an isolation material at inner walls of gate trenches along an FF′ cutting line in FIG. 16 provided by examples of the present application;

FIG. 18 is a cross-sectional view of filling an isolation material at inner walls of gate trenches to cover a gate strip and a shielding strip provided by examples of the present application;

FIG. 19 is a cross-sectional view of forming a capacitor array provided by examples of the present application;

FIGS. 20 to 26 are multiple cross-sectional views of a fabrication flow of forming a barrier layer provided by examples of the present application;

FIG. 27 is a top view of forming a barrier strip and a gate conductive connection structure provided by examples of the present application;

FIG. 28 is a cross-sectional view of forming a barrier strip and a gate conductive connection structure along a GG′ cutting line in FIG. 27 provided by examples of the present application;

FIGS. 29 and 30 are multiple cross-sectional views of a fabrication flow of forming a gate lead-out contact provided by examples of the present application;

FIG. 31 is a top view of forming a gate lead-out contact and a shielding lead-out contact provided by examples of the present application;

FIG. 32 is a cross-sectional view of forming a gate lead-out contact and a shielding lead-out contact along an HH′ cutting line in FIG. 31 provided by examples of the present application;

FIGS. 33 and 34 are multiple top views of another fabrication flow of forming a gate lead-out contact and a shielding lead-out contact provided by examples of the present application;

FIG. 35 is a top view of forming a semiconductor pillar lead-out contact provided by examples of the present application;

FIG. 36 is a cross-sectional view of forming a gate lead-out contact, a shielding lead-out contact and a semiconductor pillar lead-out contact provided by examples of the present application;

FIG. 37 is a flow diagram of a fabrication method of a semiconductor device provided by examples of the present application; and

FIG. 38 is a schematic structure diagram of a memory system provided by examples of the present application.

### DETAILED DESCRIPTION

The technical solutions in examples of the present application will be described below clearly and completely in conjunction with the drawings in the examples of the present application. Apparently, the examples described are only part of, but not all of, the examples of the present application. All other examples obtained by those skilled in the art without creative work based on the examples in the present application shall fall in the scope of protection of the present application. Furthermore, it should be understood that, the Detailed Description described herein is only used for illustrating and explaining the present application, instead of restricting the present application. In the present application, in the case where no contrary is stated, the directional words used, such as “upper” and “lower”, typically refer to upper and lower of a device in an actual using or working state, specifically in the direction of the page in the drawings, and “inner” and “outer” refer to the outline of the device.

A transistor may be used in a dynamic random access memory (DRAM) to control capacitance in each memory cell. A basic memory cell structure of the dynamic random access memory consists of one transistor and one memory capacitor, and its major working principle is to represent whether a binary bit is 1 or 0 utilizing the amount of charges stored in the capacitor.

With the development of the dynamic random access memory technology, the size of the memory cell is increasingly smaller, and its array architecture goes from 8F² to 6F² and to 4F². In addition, based on the requirements in the dynamic random access memory for ions and leak current, the architecture of the memory goes from a planar array transistor to a recess gate array transistor, then from the recess gate array transistor to a buried saddle fin array transistor, and then from the buried saddle fin array transistor to a vertical gate transistor.

In a practical application, regardless of the planar transistor, the recess gate array transistor, the buried saddle fin transistor or the vertical gate transistor, the dynamic random access memory is composed of a plurality of memory cell structures each being mainly composed of one transistor and one memory capacitor manipulated by the transistor, i.e., the dynamic random access memory comprises 1 transistor (T) and 1 capacitor (C), i.e., a 1T1C architecture, and its major working principle is to represent whether a binary bit is 1 or 0 utilizing the amount of charges stored in the capacitor.

FIG. 1 is a circuit connection diagram employing a 1T1C architecture provided in examples of the present application. As shown in FIG. 1, a drain of a transistor T is electrically connected with a bit line (BL), a source of the transistor T is electrically connected with one of electrode plates of a capacitor C, the other electrode plate of the capacitor C is grounded through a ground terminal (GND), and a gate of the transistor T is connected with a word line (WL). A voltage is applied through the word line WL to control on or off of the transistor T, and the bit line BL is used to perform a read or write operation on the capacitor C when the transistor T is turned on.

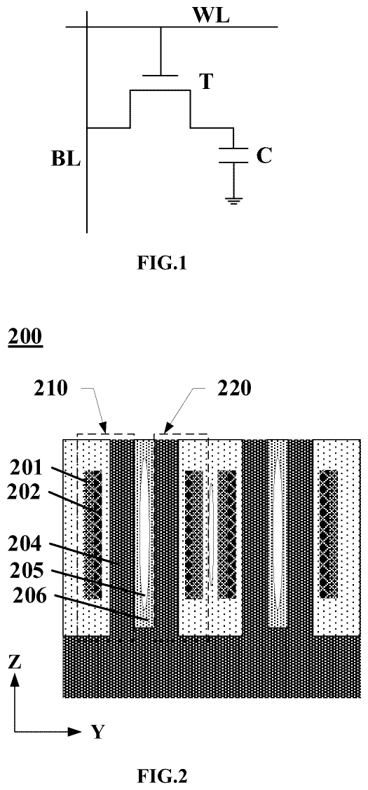

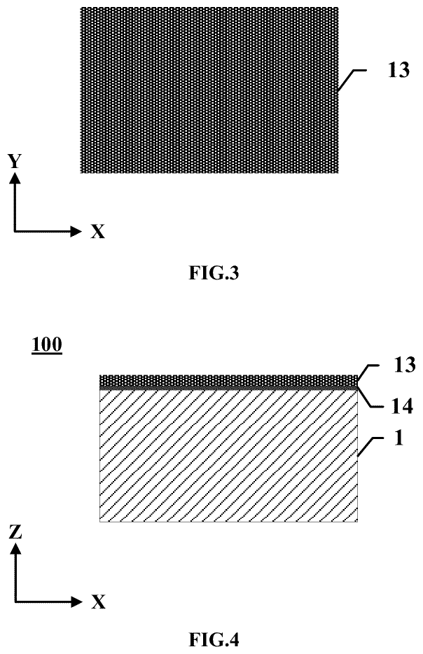

FIG. 2 is a schematic cross-sectional view of a semiconductor structure 200 provided in examples of the present application. The examples of the present application provide a semiconductor structure. As shown in FIG. 2, the semiconductor structure comprises: a first transistor 210 and a second transistor 220 that are disposed in juxtaposition along a Y axis direction and spaced apart by a first isolation structure 206, wherein the first isolation structure 206 comprises an air gap 205, and the first transistor 210 and the second transistor 220 each comprises: a gate 201 extending along a Z axis direction, a channel area 204 extending along the Z axis direction, a gate oxide layer 202 located between the gate 201 and the channel area 204 and extending along the Z axis direction, and a source (not shown in the figure) and a drain (not shown in the figure) located at two opposite ends of the channel area 204 along the Z direction respectively. The gate 201 is located on a side of the channel area 204, wherein the gate 201 of the first transistor 210 is located on one of two sides of the channel area 204 away from the first isolation structure 206, and the gate 201 of the second transistor 220 is located on one of the two sides of the channel area 204 away from the first isolation structure 206.

When a vertical gate transistor structure as shown in FIG. 2 is employed, the air gap 205 is formed in the middle of the first isolation structure 206 to improve the problem that a coupling effect easily occurs for the adjacent first transistor 210 and the second transistor 220 in the semiconductor structure. However, this semiconductor structure has high requirements on process control and has the problem of easily falling down.

In order to improve the above problem, referring to FIGS. 3 to 38, some examples of the present application provide a semiconductor device 100 and a fabrication method thereof, a memory 320 and a memory system 300. In the present application, two electrodes, i.e., a first electrode and a second electrode, are formed between adjacent semiconductor pillars 10, and a barrier strip 90 extending along a first direction X and connected with the second electrode is formed at the same end of the first electrode and the second electrode in a third direction Z. As such, the first electrode can serve as a gate strip 30, and the second electrode can serve as a shielding strip 20. The shielding strip 20 is formed at the same time as forming the gate strip 30, such that the interference between the adjacent semiconductor pillars 10 can be prevented by the shielding strip 20, thus reducing the coupling effect between the adjacent semiconductor pillars 10.

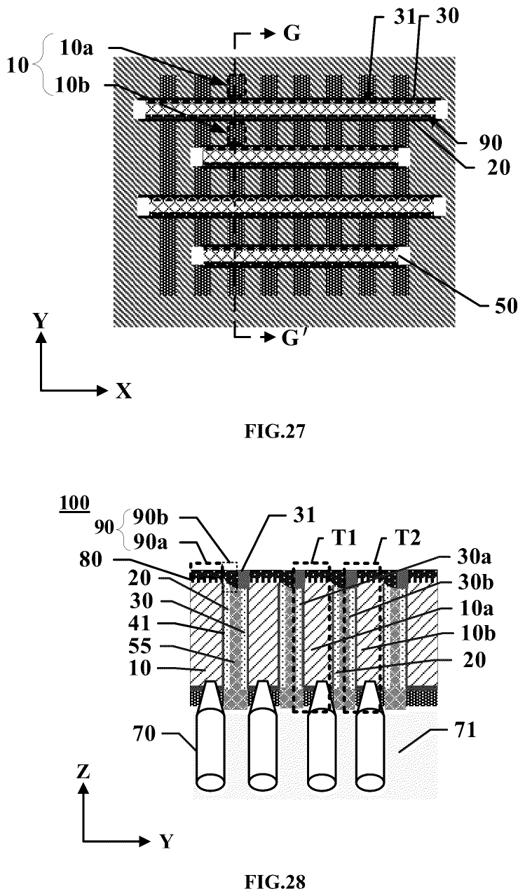

Referring to FIGS. 3 to 36, which are schematic process diagrams of a fabrication process of a semiconductor device 100 provided by some examples of the present application. First, a description is made regarding the semiconductor device 100, wherein FIG. 27 is a top view of a semiconductor structure provided by examples of the present application, FIG. 28 is a cross-sectional view of the semiconductor structure along a GG′ cutting line in FIG. 27 provided by examples of the present application, and FIG. 30 is another cross-sectional view of the semiconductor structure along the GG′ cutting line in FIG. 27 provided by examples of the present application. As shown in FIGS. 27, 28 and 30, the semiconductor device 100 comprises:
a semiconductor pillar array comprising a plurality of semiconductor pillars 10 arranged in an array along a first direction and a second direction and extending in the third direction, wherein the first direction, the second direction and the third direction intersect with each other;
a gate strip 30 and a shielding strip 20 disposed between adjacent ones of the semiconductor pillars 10 along the second direction Y, wherein the gate strip 30 and the shielding strip 20 extend along the first direction X and are spaced apart in the second direction Y; and
a barrier strip 90 extending along the first direction X, wherein the barrier strip 90 is connected with an end of the shielding strip 20 in the third direction Z, and is located on the same side of the shielding strip 20 and the gate strip 30 in the third direction Z.

In some particular examples, there is an included angle between the first direction and the second direction, there is an included angle between the third direction and a plane where the first direction and the second direction are located, and the range of the included angles is less than or equal to 90 degrees. For example, the first direction is set as an X direction, the second direction is set as a Y direction, and the third direction is set as a Z direction in some examples of the present application.

As shown in FIG. 27, the plurality of semiconductor pillars 10 include a first row of semiconductor pillars 10a and a second row of semiconductor pillars 10b arranged along the first direction X and adjacent in the second direction Y. The semiconductor pillars 10 are used to transfer charges or stop the transfer of charges under an external electric field to turn on or turn off a transistor. An extending direction of each semiconductor pillar 10 is a current direction when the transistor is turned on. In an example, as shown in FIGS. 28 and 30, the extending direction of the semiconductor pillar 10 is the third direction Z, and the plurality of semiconductor pillars 10 are distributed in an array along the first direction X and the second direction Y to form the semiconductor pillar array.

In some particular examples, as shown in FIGS. 27, 28 and 30, one gate strip 30 and one shielding strip 20 are disposed between the two adjacent ones of the semiconductor pillars 10 along the second direction Y. In addition, as shown in FIG. 27, the gate strip 30 between adjacent ones of the semiconductor pillars 10 along the second direction Y extends along the first direction X, the shielding strip 20 between adjacent ones of the semiconductor pillars 10 along the second direction Y extends along the first direction X, and one gate strip 30 and one shielding strip 20 between every two adjacent ones of the semiconductor pillars 10 along the second direction Y are spaced apart from each other, that is, the gate strip 30 and the shielding strip 20 between adjacent ones of the semiconductor pillars 10 are not in contact and have a spacing.

In some particular examples, as shown in FIGS. 28 and 30, the semiconductor structure is further provided with the barrier strip 90 extending along the first direction X, wherein the barrier strip 90 is in contact with or is connected with the end of the shielding strip 20 in the third direction Z, and is located on the same side of the shielding strip 20 and the gate strip 30 in the third direction Z, i.e., the barrier strip 90, the end of the shielding strip 20 connected with the barrier strip 90 in the third direction Z, and an end of the gate strip 30 connected with a gate conductive connection structure 31 in the third direction Z formed in examples below are located on the same side. As such, the gate strip 30 and the shielding strip 20 between adjacent ones of the semiconductor pillars 10 along the second direction Y can be isolated by the barrier strip 90, and since the barrier strip 90 has a function of insulation, the barrier strip 90 can isolate the shielding strip 20 and the gate strip 30 better.

In some particular examples, as shown in FIGS. 28 and 30, the barrier strip 90 is located between the shielding strip 20 and the gate strip 30 and is in contact connection with the end of the shielding strip 20 in the third direction Z (e.g., an end of the semiconductor pillar 10 away from a capacitor structure 70 in examples below in the third direction Z), and the barrier strip 90 and the gate strip 30 have a spacing in the second direction Y.

In some particular examples, the barrier strip 90 may be also located at the same end of the shielding strip 20 and the semiconductor pillar 10 in the third direction Z. For example, as shown in FIGS. 28 and 30, a first barrier portion 90a of the barrier strip 90 is located at the same end of the shielding strip 20 and the gate strip 30 between adjacent ones of the semiconductor pillars 10 in the third direction Z, that is, the first barrier portion 90a is connected with the end of the shielding strip 20 in the third direction Z. A second barrier portion 90b of the barrier strip 90 is located at the same end of adjacent ones of the semiconductor pillars 10 in the third direction Z, that is, the second barrier portion 90b is connected with an end of the semiconductor pillar 10 in the third direction Z. Moreover, the first barrier portion 90a connected with the end of the shielding strip 20 in the third direction Z and the second barrier portion 90b connected with the end of the semiconductor pillar 10 in the third direction Z are located on the same side in the third direction Z.

In some examples, the first barrier portion 90a and the second barrier portion 90b are shown in FIGS. 28 and 30. As shown in FIG. 28, the cross-sectional shape of the second barrier portion 90b may be a sector. As shown in FIG. 30, the cross-sectional shape of the second barrier portion 90b may be a rectangle. Of course, the cross-sectional shape of the second barrier portion 90b may be also an inverted trapezoid, an arc, etc.

In some examples, as shown in FIG. 28, the first barrier portion 90a may be removed to connect a bit line BL in examples below.

In some particular examples, a composition material of the barrier strip 90 may include an insulation material, such as silicon oxide, silicon nitride, silicon oxynitride, aluminum oxide, polysiloxane or polysilazane, etc. Here, silicon oxide refers to a silicon-oxygen compound, such as SixOy, and silicon nitride refers to a nitrogen-silicon compound, such as SixNy.

In some examples, the semiconductor device 100 further comprises: a gate conductive connection structure 31, wherein the gate conductive connection structure 31 extends along the first direction X, and is located between the end of the gate strip 30 in the third direction Z and the barrier strip 90, and is at least partially in juxtaposition to the barrier strip 90.

In some particular examples, as shown in FIGS. 28 to 30, the end of the gate strip 30 in the third direction Z is connected with the gate conductive connection structure 31. In the third direction Z, the gate conductive connection structure 31 is located between the gate strip 30 and the barrier strip 90, the gate conductive connection structure 31 is in contact connection with the end of the gate strip 30 in the third direction Z (e.g., an end of the semiconductor pillar 10 away from a capacitor structure 70 in examples below in the third direction Z), and the gate conductive connection structure 31 is adjacent to the barrier strip 90. That is to say, the gate conductive connection structure 31 connected with the gate strip 30 and the barrier strip 90 in contact with the shielding strip 20 are located on the same side in the third direction Z, and along the second direction Y, the gate conductive connection structure 31 is adjacent to the barrier strip 90.

In some particular examples, a composition material of the gate conductive connection structure 31 may comprise a conductive material, including, but not limited to, tungsten (W), cobalt (Co), copper (Cu), aluminum (Al), silicides or any combination thereof.

In some examples, the semiconductor device 100 further comprises: a gate lead-out contact 32 located at an end of the semiconductor pillar array in the third direction Z, wherein the gate lead-out contact 32 is connected with the gate conductive connection structure 31.

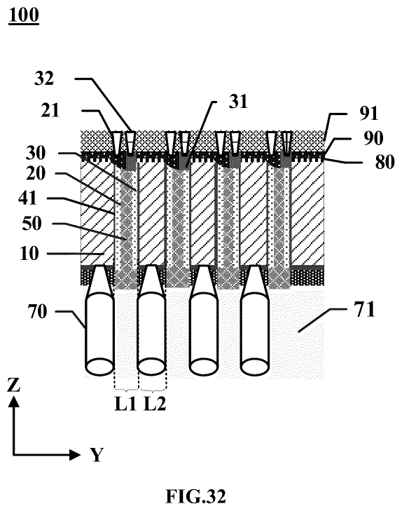

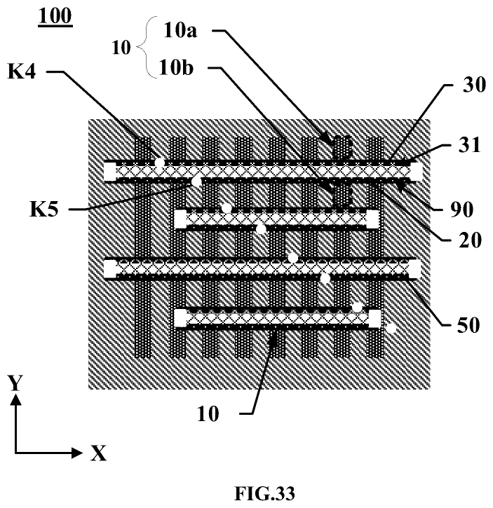

In some particular examples, as shown in FIGS. 30 and 32, an end of each gate conductive connection structure 31 away from the gate strip 30 in the third direction is connected with the gate lead-out contact 32, i.e., the gate conductive connection structure is located between the gate lead-out contact 32 and the gate strip 30 in the third direction Z.

In some particular examples, a composition material of the gate lead-out contact 32 may comprise a conductive material, including, but not limited to, tungsten (W), cobalt (Co), copper (Cu), aluminum (Al), silicides or any combination thereof. The materials of the gate lead-out contact 32 and the gate conductive connection structure 31 may be either the same or different. According to the present application, a connection of the gate strip 30 is led out through the gate lead-out contact 32 and the gate conductive connection structure 31, which is beneficial to the process flow and can improve reliability.

In some examples, the semiconductor device 100 further comprises: a shielding lead-out contact 21 located at the end of the semiconductor pillar array in the third direction Z, wherein the shielding lead-out contact 21 is connected with the shielding strip 20.

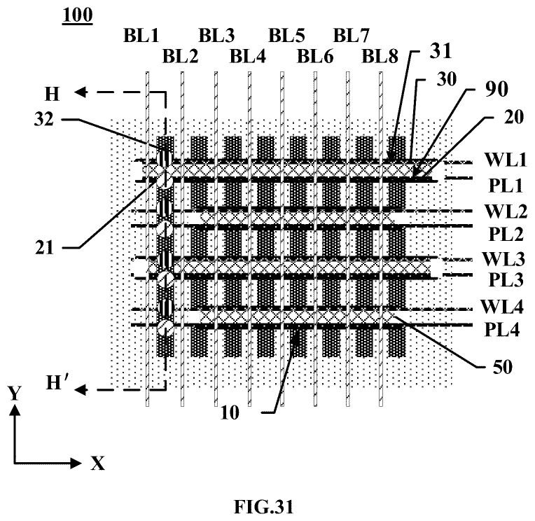

In some particular examples, as shown in FIGS. 31, 32 and 34, the end of the shielding strip 20 in the third direction Z is connected with the shielding lead-out contact 21. In some examples, for example, when being located at a non-end portion of the shielding strip 20, the shielding lead-out contact 21 passes through the barrier strip 90 along the third direction Z, and the shielding lead-out contact 21 is in contact connection with the end of the shielding strip 20 in the third direction Z (e.g., the end of the semiconductor pillar 10 away from the capacitor structure 70 in the examples below in the third direction Z) through the barrier strip 90. That is to say, the shielding lead-out contact 21 connected with the shielding strip 20 and the barrier strip 90 connected with the shielding strip 20 are located on the same side in the third direction Z, and along the third direction Z, the shielding lead-out contact 21 and the shielding strip 20 are located on two opposite sides of the barrier strip 90.

In some particular examples, a composition material of the shielding lead-out contact 21 may comprise a conductive material, including, but not limited to, tungsten (W), cobalt (Co), copper (Cu), aluminum (Al), silicides or any combination thereof. The materials of the shielding lead-out contact 21 and the shielding strip 20 may be either the same or different. In the present application, the shielding lead-out contact 21 electrically interconnects with the shielding strip 20, i.e., the shielding lead-out contact 21 can be connected with a common terminal to make the shielding strip 20 produce an effect of shielding by applying a fixed voltage to the shielding strip 20 through the shielding lead-out contact 21.

In some particular examples, the common terminal may comprise a low voltage terminal and a ground terminal, wherein the low voltage may include −0.5 V, −1 V, etc. In some examples, the shielding strip 20 is connected with the common terminal. During a practical application, the shielding strip 20 may be disposed as being powered separately instead of being connected with the common terminal according to requirements. In some examples of the present application, the shielding strip 20 may shield interference between adjacent ones of the semiconductor pillars 10 by applying the low voltage to the shielding strip 20 or grounding the shielding strip 20.

In some examples, the semiconductor device 100 further comprises: a semiconductor pillar lead-out contact 11 at the end of the semiconductor pillar array in the third direction Z, wherein the semiconductor pillar lead-out contact 11 is connected with the semiconductor pillar 10.

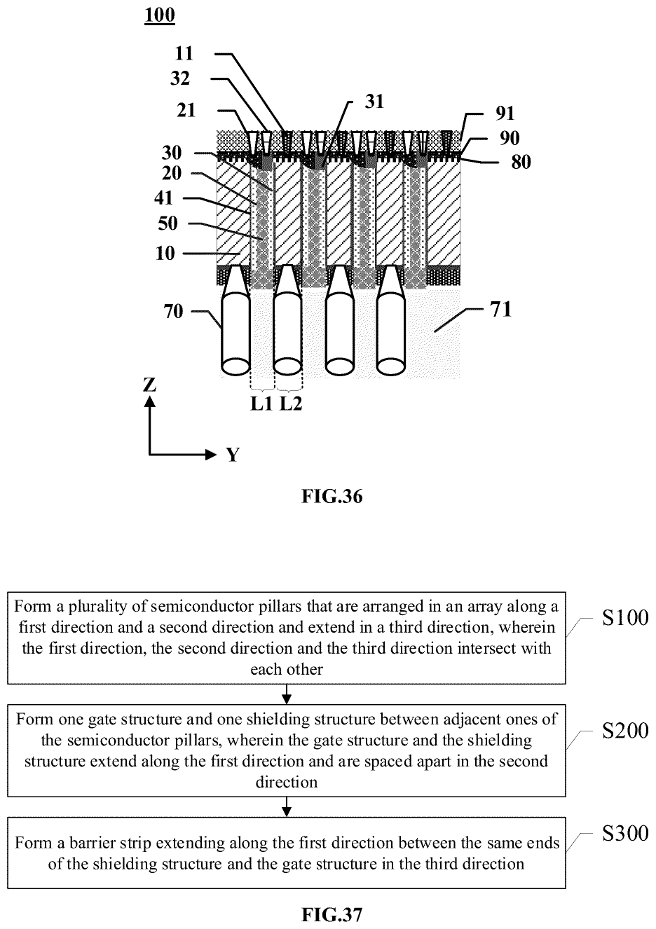

In some particular examples, as shown in FIGS. 35 and 36, the end of the semiconductor pillar 10 in the third direction Z is connected with the semiconductor pillar lead-out contact 11. The semiconductor pillar lead-out contact 11 passes through the barrier strip 90 covering the semiconductor pillar 10 along the third direction Z, such that the semiconductor pillar lead-out contact 11 passes through the barrier strip 90 and is in contact connection with the end of the semiconductor pillar 10 in the third direction Z (e.g., the end of the semiconductor pillar 10 away from the capacitor structure 70 in the examples below in the third direction Z). That is to say, the semiconductor pillar lead-out contact 11 connected with the semiconductor pillar 10 and the barrier strip 90 connected with the semiconductor pillar 10 are located on the same side in the third direction Z, and along the third direction Z, the semiconductor pillar lead-out contact 11 is connected with an end of the shielding strip 20.

In some examples, the first barrier portion 90a connected with the end of the semiconductor pillar 10 along the third direction Z as shown in FIG. 28 may be removed.

In some particular examples, a composition material of the semiconductor pillar lead-out contact 11 may comprise a conductive material, including, but not limited to, tungsten (W), cobalt (Co), copper (Cu), aluminum (Al), silicides or any combination thereof. The materials of the semiconductor pillar lead-out contact 11 and the semiconductor pillar 10 may be either the same or different. In the present application, the semiconductor pillar lead-out contact 11 electrically interconnects with the semiconductor pillar 10, and the ends of the plurality of semiconductor pillars 10 along the third direction Z may be connected with the same bit line BL through the semiconductor pillar lead-out contacts 11. Of course, in some examples, the semiconductor pillar lead-out contact 11 may be alternatively formed as a bit line BL, that is, in the examples of the present application, a connection of the bit line BL may be led out by the semiconductor pillar lead-out contact 11, and the connection of the bit line BL may be not led out by the semiconductor pillar lead-out contact 11, i.e., the bit line BL connecting the ends of the plurality of semiconductor pillars 10 along the third direction Z may be directly formed at the ends of the plurality of semiconductor pillars 10 along the third direction Z.

In an example, as shown in FIG. 35, the semiconductor pillar lead-out contact 11 is formed at the bottom of each of the plurality of semiconductor pillars 10 arranged in an array, and the corresponding semiconductor pillars 10 may be led out by the plurality of semiconductor pillar lead-out contacts 11 arranged as being spaced apart along the first direction X and the second direction Y as shown in FIG. 35, that is, eight columns of the semiconductor pillar lead-out contacts 11 are connected with a first bit line BL1 to an eighth bit line BL8 sequentially and respectively. It is to be noted that, the number of the semiconductor pillar lead-out contacts 11 illustrated in the examples of the present application is only an example, and other numbers of the semiconductor pillar lead-out contacts 11 also fall within protection scope of the present application.

In some particular examples, the semiconductor device 100 may further comprise an insulation layer 91 extending along the second direction Y and located at the end of the semiconductor pillar array in the third direction Z. As shown in FIG. 32, in the third direction Z, the insulation layer 91 covers the barrier strip 90, the gate conductive connection structure 31, the gate lead-out contact 32, the shielding lead-out contact 21 and the semiconductor pillar lead-out contact 11.

In some particular examples, the semiconductor device 100 may further comprise an isolation layer 80 extending along the second direction Y and located at the end of the semiconductor pillar array in the third direction Z. As shown in FIG. 32, in the third direction Z, the insulation layer 80 covers the end of the semiconductor pillar 10 away from the capacitor structure 70 in the examples below along the third direction Z, that is, as shown in FIG. 32, along the third direction Z, the isolation layer 80 and the insulation layer 91 are located on two opposite sides of the barrier strip 90 respectively, and the isolation layer 80 covers each semiconductor pillar 10, and the insulation layer 91 covers the barrier strip 90, the gate conductive connection structure 31, the gate lead-out contact 32, the shielding lead-out contact 21 and the semiconductor pillar lead-out contact 11 located on the same side along the third direction Z.

In some particular examples, composition materials of the isolation layer 80 and the insulation material 91 may each include a combination of any one or more of silicon oxide, silicon nitride, silicon oxynitride, aluminum oxide, polysiloxane or polysilazane or other insulation materials. In the examples of the present application, the materials of the isolation layer 80 and the insulation material 91 may be either the same or different.

In some examples, the semiconductor device 100 further comprises:
a plurality of the gate strips 30 arranged as being spaced apart between rows of the semiconductor pillars 10 along the second direction Y;
a plurality of the shielding strips 20 arranged as being spaced apart between the rows of the semiconductor pillars 10 along the second direction Y and arranged as being staggered and spaced apart with the plurality of gate strips 30;
a plurality of the barrier strips 90 arranged as being spaced apart between the rows of the semiconductor pillars 10 along the second direction Y; and
a plurality of the gate conductive connection structures 31 arranged as being spaced apart between the rows of the semiconductor pillars 10 along the second direction Y.

In some particular examples, as shown in FIG. 27, along the first direction X, the plurality of semiconductor pillars 10 are arranged as being spaced apart, and along the second direction Y, the plurality of semiconductor pillars 10 are arranged as being spaced apart, that is, the plurality of semiconductor pillars 10 are arranged in an array along the first direction X and the second direction Y. As shown in FIGS. 27, 28 and 31, the plurality of semiconductor pillars 10 are arranged in an array along the first direction X and the second direction Y, the gate strips 30 in adjacent ones of the semiconductor pillars 10 along the second direction Y are located on a side of each semiconductor pillar 10, that is, the plurality of gate strips 30 are arranged as being spaced apart between the rows of the semiconductor pillars 10 along the second direction Y, and the plurality of gate strips 30 are located on a side of the semiconductor pillar 10 along the second direction Y. The shielding strips 20 in adjacent ones of the semiconductor pillars 10 along the second direction Y are located on the other side of each semiconductor pillar 10, that is, the plurality of shielding strips 20 are arranged as being spaced apart between the rows of the semiconductor pillars 10 along the second direction Y, and the plurality of shielding strips 20 are located on the other side of the semiconductor pillar 10 along the second direction Y. In addition, along the second direction Y, the plurality of gate strips 30 and the plurality of shielding strips 20 are arranged as being staggered, and along the second direction Y, the gate strips 30 and the shielding strips 20 in adjacent ones of the semiconductor pillars 10 have spacing therebetween.

In some particular examples, as shown in FIGS. 28 and 30, the semiconductor structure is further provided with a plurality of barrier strips 90 extending along the first direction X, an end of each shielding strip 20 in the third direction Z is connected with the respective barrier strip 90, and the barrier strips 90 connected with the plurality of shielding strips 20 respectively are located at the same end in the third direction Z. The barrier strip 90 is in contact connection with the end of the shielding strip 20 in the third direction Z (e.g., the end of the semiconductor pillar 10 away from the capacitor structure 70 in the examples below in the third direction Z), the barrier strip 90 is located on the same side of the shielding strip 20 and the gate strip 30 in the third direction Z, and the barrier strip 90 and the gate strip 30 have a spacing in the second direction Y. As such, the gate strip 30 and the shielding strip 20 between adjacent ones of the semiconductor pillars 10 along the second direction Y can be isolated by the barrier strip 90, and since the barrier strip 90 has a function of insulation, the shielding strip 20 in contact connection with the barrier strip 90 can produce an effect of shielding, thereby achieving an improved coupling effect between adjacent transistors in the second direction Y, reducing the interference between the adjacent transistors and improving yield and reliability of the memory.

In some particular examples, as shown in FIG. 30, along the second direction Y, the plurality of barrier strips 90 can be located on a side of the semiconductor pillar 10. Of course, as shown in FIG. 28, along the second direction Y, the plurality of barrier strips 90 can be located on the other side of the semiconductor pillar 10. It is to be noted that the composition material of the barrier strip 90 may be referred to the above examples, which is no longer repeated here.

In an example, as shown in FIG. 28, a first transistor T1 comprises a gate strip 30a and a semiconductor pillar 10a, a second transistor T2 comprises a gate strip 30b and a semiconductor pillar 10b, and the shielding strip 20 in contact connection with the barrier strip 90 is disposed between the semiconductor pillar 10a and the semiconductor pillar 10b. As such, the coupling effect between the first transistor T1 and the second transistor T2 can be improved by the shielding strip 20 in contact connection with the barrier strip 90, that is, when the first transistor T1 is turned on, the semiconductor pillar 10a region of the first transistor T1 becomes a high voltage, the shielding strip 20 between the first transistor T1 and the second transistor T2 may shield interference between electrons in the semiconductor pillar 10a of the first transistor T1 and electrons in the semiconductor pillar 10b of the second transistor T2, thereby reducing the problem of the interference of the first transistor T1 being turned on to the second transistor T2.

In some particular examples, as shown in FIGS. 28 to 30 and 32 to 33, the end of each gate strip 30 in the third direction Z is connected with the gate conductive connection structure 31, and the gate conductive connection structures 31 connected with the plurality of gate strips 30 respectively are located at the same end in the third direction, wherein along the third direction Z, the gate conductive connection structure 31 is located between the gate strip 30 and the barrier strip 90, the gate conductive connection structure 31 is in contact connection with the end of the gate strip 30 in the third direction Z (e.g., the end of the semiconductor pillar 10 away from the capacitor structure 70 in the examples below in the third direction Z), and along the second direction Y, the gate conductive connection structure 31 is adjacent to the barrier strip 90.

In some particular examples, as shown in FIG. 28, along the second direction Y, the plurality of gate conductive connection structures 31 may be located on a side between adjacent ones of the semiconductor pillars 10, and in this case, in the second direction Y, the plurality of barrier strips 90 are located on the other side between the adjacent ones of the semiconductor pillars 10. Of course, as shown in FIG. 30, along the second direction Y, the plurality of gate conductive connection structures 31 may be located on the other side of the semiconductor pillar 10, and in this case, in the second direction Y, the plurality of barrier strips 90 are located on a side between adjacent ones of the semiconductor pillars 10. In a word, the gate conductive connection structure 31 and the barrier strip 90 are located on the same side of the semiconductor pillar 10 along the third direction Z, and the gate conductive connection structure 31 and the barrier strip 90 are located on different sides of adjacent ones of the semiconductor pillars 10 along the second direction Y. It is to be noted that the composition material of the gate conductive connection structure 31 may be referred to the above examples, which is no longer repeated here.

In some examples, the semiconductor device 100 further comprises a plurality of gate lead-out contacts 32, wherein one of the gate lead-out contacts 32 corresponds to one of the gate conductive connection structures 31, and the plurality of gate lead-out contacts 32 are synchronously arranged as being spaced apart along the first direction X and the second direction Y in a staircase distribution.

In some examples, the semiconductor device 100 further comprises a plurality of shielding lead-out contacts 21, wherein one of the shielding lead-out contacts 21 corresponds to one of the shielding strips 20, and the plurality of shielding lead-out contacts 21 are synchronously arranged as being spaced apart along the first direction X and the second direction Y in a staircase distribution.

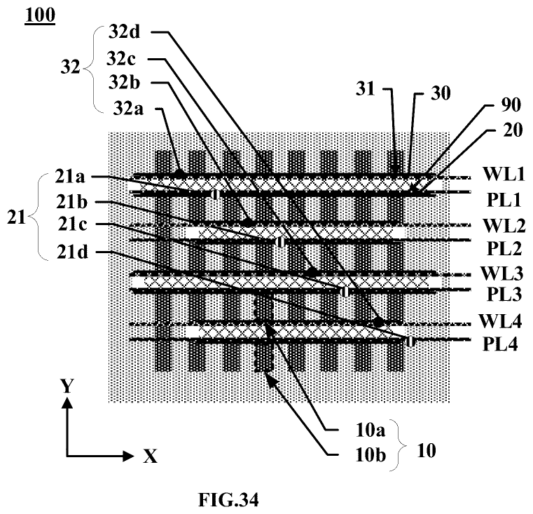

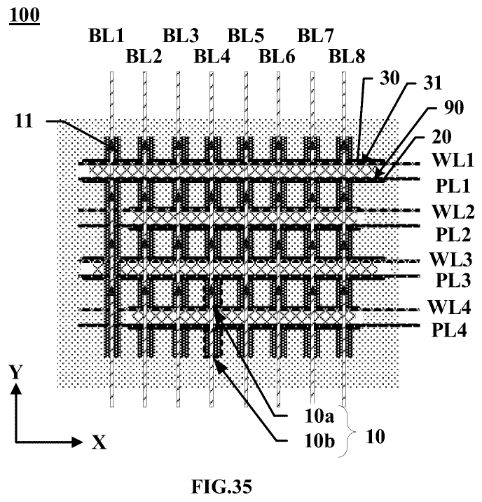

In a particular example, as shown in FIGS. 30, 34 and 32, the semiconductor device 100 comprises a gate lead-out contact 32a, a gate lead-out contact 32b, a gate lead-out contact 32c and a gate lead-out contact 32d that are simultaneously or synchronously arranged as being spaced apart along the first direction X and the second direction Y according to an arrangement order of the four gate strips 30 of the example as shown in FIGS. 30 and 32, such that they are arranged in a shape of staircase. The semiconductor device 100 comprises a shielding lead-out contact 21a, a shielding lead-out contact 21b, a shielding lead-out contact 21c and a shielding lead-out contact 21d that are simultaneously or synchronously arranged as being spaced apart along the first direction X and the second direction Y according to an arrangement order of the four shielding strips 20 of the example as shown in FIGS. 32 and 34, such that they are arranged in a shape of staircase. Moreover, the gate strip 30 of the gate lead-out contact 32 between adjacent ones of the semiconductor pillars 10 is away from an end of the capacitor structure 70 in the examples below along the third direction Z, and the shielding strip 20 of the shielding lead-out contact 21 between adjacent ones of the semiconductor pillars 10 is away from the end of the capacitor structure 70 in the examples below along the third direction Z. It is to be noted that, the composition materials of the gate lead-out contact 32 and the shielding lead-out contact 21 may be referred to the above examples, which is no longer repeated here.

In some examples, as shown in FIGS. 31 and 32, the semiconductor device 100 further comprises a plurality of gate lead-out contacts 32 and a plurality of shielding lead-out contacts 21, wherein one of the gate lead-out contacts 32 corresponds to one of the gate conductive connection structures 31, one of the shielding lead-out contacts 21 corresponds to one of the shielding strips 20, and the plurality of gate lead-out contacts 32 and the plurality of shielding lead-out contacts 21 are arranged as being staggered and spaced apart along the second direction Y.

In an example, as shown in FIG. 31, the four gate strips 30 extending along the first direction X are arranged as being spaced apart along the second direction Y. A side of each gate strip 30 close to an isolation structure 50 in examples below along the second direction Y is connected with one gate conductive connection structure 31. One gate conductive connection structure 31 is correspondingly connected with one gate lead-out contact 32. The four gate strips 30 are led out through the four gate lead-out contacts 32 arranged as being spaced apart and the respective gate conductive connection structures 31 connected therewith, that is, the four gate strips 30 are connected with a first word line WL1, a second word line WL2, a third word line WL3 and a fourth word line WL4 sequentially and respectively. Similarly, the four shielding strips 20 extending along the first direction X are arranged as being spaced apart along the second direction Y. A side of each shielding strip 20 close to the isolation structure 50 in the examples below along the second direction is connected with one barrier strip 90. One shielding strip is correspondingly connected with one shielding lead-out contact 21. The four shielding strips 20 are led out through the four shielding lead-out contacts 21 arranged as being spaced apart, that is, the four shielding strips 20 are connected with a first plate line PL1, a second plate line PL2, a third plate line PL3 and a fourth plate line PL4 sequentially and respectively. A fixed voltage may be applied through a plate line PL to the shielding strip 20 connected therewith, such that the shielding strip 20 can shield the interference between adjacent ones of the semiconductor pillars 10. It is to be noted that, the number of the gate lead-out contacts 32 and the shielding lead-out contacts 21 illustrated in the examples of the present application is only an example, and other numbers of the gate lead-out contacts 32 and the shielding lead-out contacts 21 also fall within protection scope of the present application.

In some examples, as shown in FIGS. 32 and 34, the semiconductor device 100 further comprises a plurality of gate lead-out contacts 32 and a plurality of shielding lead-out contacts 21, wherein one of the gate lead-out contacts 32 corresponds to one of the gate conductive connection structures 31, one of the shielding lead-out contacts 21 corresponds to one of the shielding strips 20, and the plurality of gate lead-out contacts 32 and the plurality of shielding lead-out contacts 21 are synchronously arranged as being staggered and spaced apart along the first direction X and the second direction Y in a staircase distribution.

In an example, as shown in FIG. 34, four gate strips 30 and four shielding strips 20 may be led out similarly with reference to FIG. 31. FIG. 34 differs from FIG. 31 in that the plurality of gate lead-out contacts 32 and the plurality of shielding lead-out contacts 21 in FIG. 34 are arranged as being staggered and spaced apart along the second direction Y in a staircase distribution.

In some examples, a cross-sectional dimension of the semiconductor pillar 10 in the second direction Y is equal to a spacing dimension between two adjacent ones of the semiconductor pillars 10.

In some particular examples, as shown in FIG. 32, along the second direction Y, the cross-sectional dimension L2 of each of semiconductor pillars 10 in the second direction Y is equal to the spacing dimension L1 between adjacent ones of the semiconductor pillars 10. Due to process precision control, “equal to” in this example includes “approximately equal to” or “roughly equal to”. In some examples of the present application, the two electrodes, i.e., the first electrode and the second electrode, are formed between adjacent ones of the semiconductor pillars 10, and the barrier strip 90 extending along the first direction X and connected with the second electrode is formed at the same end of the first electrode and the second electrode in the third direction Z. As such, the first electrode can serve as the gate strip 30, and the second electrode can serve as the shielding strip 20, there is no need to directly form an air gap or other shielding isolation structure 50 between adjacent ones of the semiconductor pillars 10, and the shielding strip 20 may be formed by the barrier strip 90 at the same time as forming the gate strip 30, such that the interference of the gate strip 30 to the adjacent semiconductor pillar 10 can be shielded, thus reducing the coupling effect between adjacent ones of the semiconductor pillars 10. Moreover, along the second direction Y, the cross-sectional dimension L2 of each of semiconductor pillars 10 in the second direction Y is equal to the spacing dimension L1 between adjacent ones of the semiconductor pillars 10, which reduces the load effect, and reduces process control difficulty.

In some examples, a difference between the cross-sectional dimension of the semiconductor pillar 10 in the second direction Y and the spacing dimension between two adjacent ones of the semiconductor pillars 10 is less than a preset value.

In some particular examples, as shown in FIG. 32, along the second direction Y, the dimension difference between the cross-sectional dimension L2 of each of semiconductor pillars 10 in the second direction Y and the spacing dimension L1 between adjacent ones of the semiconductor pillars 10 is less than a process-based or apparatus-based precision requirement, or a set numerical value as required by the product. For example, an absolute value of the difference value between the spacing dimension L1 and the cross-sectional dimension L2 is less than other feasible numerical values, i.e., |L1-L2|<ΔL, where ΔL refers to a preset value.

In some examples, the semiconductor device 100 further comprises:
a first oxide layer 41 between the semiconductor pillar 10 and the gate strip 30 and between the semiconductor pillar 10 and the shielding strip 20; and
an isolation structure 50 between the gate strip 30 and the shielding strip 20.

In some particular examples, as shown in FIGS. 18 to 26, 28 to 30 and 32, the semiconductor device 100 further comprises the first oxide layer 41 and the isolation structure 50. The first oxide layer 41 is disposed between the semiconductor pillar 10 and the gate strip 30 along the second direction Y, and the first oxide layer 41 is disposed between the semiconductor pillar 10 and the shielding strip 20 along the second direction Y. In addition, the isolation structure 50 is disposed between the gate strip 30 and the shielding strip 20 along the second direction Y. As shown in FIGS. 18 to 26, 28 to 30 and 32, the semiconductor pillar 10, the first oxide layer 41, the gate strip 30, the isolation structure 50, the shielding strip 20, the first oxide layer 41 and the semiconductor pillar 10 are arranged sequentially along the second direction Y.

In some examples, the gate strip 30 and the shielding strip 20 are disposed between adjacent ones of the semiconductor pillars 10 in the second direction Y, and a spacing distance between the semiconductor pillar 10 and the shielding strip 20 is the same as a spacing distance between the adjacent semiconductor pillar 10 and the gate strip 30. That is to say, in the second direction Y, one gate strip 30 and one shielding strip 20 are located on different sidewalls of adjacent ones of the semiconductor pillars 10 respectively, and positions of the shielding strip 20 and the gate strip 30 are in mirror symmetry.

As shown in FIG. 2, the first isolation structure 206 is located in a middle position between the two adjacent gates 201 along the second direction Y, and one first isolation structure 206 is disposed in a middle position between the adjacent channel areas 204 in the second direction Y. That is to say, distances between the first isolation structure 206 and the adjacent channel areas 204 in the second direction Y are the same, and distances between the first isolation structure 206 and the adjacent gates 201 in the second direction Y are the same. Different from what is shown in FIG. 2, in the present application, as shown in FIGS. 11 to 28, gate trenches K2 are formed synchronously, the first electrode and the second electrode are formed on different sidewalls of the gate trench along the second direction Y, and the barrier strip 90 is formed on a side of the second electrode on a sidewall along the third direction Z, such that the second electrode connected with the barrier strip 90 forms the shielding strip 20 having a shielding function, and the first electrode not connected with the barrier strip 90 forms the gate strip. Compared with FIG. 2, a trench is additionally formed between adjacent transistors, to obtain an isolation groove for forming the first isolation structure 206. In the present application, a plurality of gate grooves arranged with equal spacing are directly utilized to form conductive layers disposed in mirror symmetry in conjunction with the barrier strips to form the gate strips 30 and the shielding strips 20, which reduces the process control difficulty, can further enhance strength of the semiconductor pillars 10, and improves anti-falling capability of the semiconductor device 100.

In some particular examples, a composition material of the first oxide layer 41 may include silicon oxide, silicon oxynitride, etc.

In some particular examples, a composition material of the isolation structure 50 may include a combination of any one or more of silicon oxide, silicon nitride, silicon oxynitride, aluminum oxide, polysiloxane or polysilazane or other insulation materials

In some examples, the semiconductor device 100 further comprises: a capacitor array 71 at the other end of the semiconductor pillar array in the third direction Z, wherein the capacitor array 71 comprises a plurality of capacitor structures 70 arranged in an array along the first direction X and the second direction Y and extending in the third direction Z, and the capacitor structures 70 each comprises a first electrode layer (not shown in the figures) connected with the other end of the semiconductor pillar 10 in the third direction Z, and a capacitor dielectric layer (not shown in the figures) and a second electrode layer (not shown in the figures) within the first electrode layer.

In some particular examples, as shown in FIGS. 28, 30 and 32, the semiconductor device 100 further comprises the capacitor array 71, wherein the capacitor array 71 comprises the plurality of capacitor structures 70 extending in the third direction Z, the plurality of capacitor structures 70 are arranged in an array along the first direction X and the second direction Y, and the other end of each semiconductor pillar 10 along the third direction Z (i.e., the other end and an end of the semiconductor pillar 10 connected with the barrier strip 90 and the gate conductive connection structure 31 are two opposite ends along the third direction Z) is connected with one of the capacitor structures 70. Moreover, each capacitor structure 70 comprises the first electrode layer connected with a source of the semiconductor pillar 10.

The gate strip 30 is formed on the sidewall of each semiconductor pillar 10 of the semiconductor pillar array. The gate strips 30 of all the semiconductor pillars 10 in the same column (i.e., the semiconductor pillars 10 arranged as being spaced apart along the second direction Y) are connected to form a word line. A source (not shown in the figures) is formed at an end of each semiconductor pillar 10 of the transistor array along the third direction Z, and is connected with the first electrode layer of the capacitor structure 70. A drain (not shown in the figures) is formed at the other end of each semiconductor pillar 10 of the transistor array along the third direction Z, and the drains of all the semiconductor pillars 10 in the same column (i.e., the semiconductor pillars 10 arranged as being spaced apart along the first direction X) are connected to form a bit line BL (not shown in the figures). The semiconductor pillar 10 in the above-mentioned semiconductor device 100 extends along the third direction Z, the source and the drain are formed at the two opposite ends of the semiconductor pillar 10 along the third direction Z respectively, and along the third direction Z, the capacitor structure 70 and the bit line BL are located on two opposite sides of the semiconductor pillar 10 respectively, such that fabrication may be performed on two sides of a substrate 1 respectively, thus improving process manufacturing efficiency.

It may be understood that, the source and the drain of the semiconductor pillar 10 are of a relative concept, and the source and the drain may be any surface of the semiconductor pillar 10 along the third direction Z.

One capacitor structure 70 and one transistor constitute one DRAM memory cell. Through turning on and off of the transistor, selection and unselection of the connected capacitor structure 70 are achieved, which, in turn, achieves read, write or erase operation of the selected memory cell. The examples of the present application do not limit the number of the capacitor structures 70 and the transistors, and it is possible that the capacitor array 71 is coupled with a transistor array (including the plurality of transistors arranged in an array along the first direction X and the second direction Y) to constitute a DRAM array memory structure.

It may be understood that, the source and the drain of the transistor are of a relative concept, and are related to the way the transistor is actually connected to the circuit, but unrelated to physical positions of the source and the drain in the transistor. In some examples, when the transistor is connected into a circuit, an input end of the transistor connected into the circuit may serve as the source, an output end serves as the drain, and carriers flow from the source into the drain. In order to better explain a coupling relationship between the capacitor structure 70 and the transistor in the examples of the present application, an end of the transistor coupled with the capacitor structure 70 serves as the drain, and the source of the transistor may be coupled with the bit line BL that applyies an operation voltage.

Examples of the present application further provide a fabrication method of a semiconductor device 100. The semiconductor device 100 in the above examples may be manufactured by the fabrication method of the semiconductor device 100 below. FIG. 37 is a flow diagram of the fabrication method of the semiconductor device 100 in the examples of the present application, which, as shown in FIG. 37, comprises:

S100, forming a plurality of semiconductor pillars 10, wherein the plurality of semiconductor pillars 10 are arranged in an array in a first direction X and a second direction Y and extend in a third direction Z, and the first direction X, the second direction Y and the third direction Z intersect with each other.

In some examples, the forming the plurality of semiconductor pillars 10 comprises:
S110, providing a substrate 1.

In some particular examples, the substrate 1 comprises a material for fabricating the semiconductor device 100, and the material of the substrate 1 may include silicon (e.g., monocrystalline silicon, polysilicon), silicon germanium (SiGe), silicon carbide (SiC), gallium nitride (GaN), indium phosphide (InP), gallium arsenide (GaAs), germanium (Ge), silicon on insulator (SOI), germanium on insulator (GOI) or any suitable combination thereof. The substrate 1 may comprise a wafer formed from cylindrical monocrystalline silicon after steps such as grinding, polishing and dicing, etc.

In some particular examples, before forming isolation trenches K1 of operation S120, first, a first dielectric layer 14 covering the substrate 1 is formed by deposition along the third direction Z, and then, a second oxide layer (liner oxide) 13 covering the first dielectric layer 14 is formed by deposition along the third direction Z at a high temperature to repair a surface of the substrate 1, so as to form a structure in which the substrate 1, the first dielectric layer 14 and the second oxide layer 13 are stacked sequentially along the third direction Z as shown in FIGS. 3 and 4.

In some particular examples, composition materials of the second oxide layer 13 and the first dielectric layer 14 may include any one or more of silicon oxide, silicon nitride, aluminum oxide or silicon oxynitride.

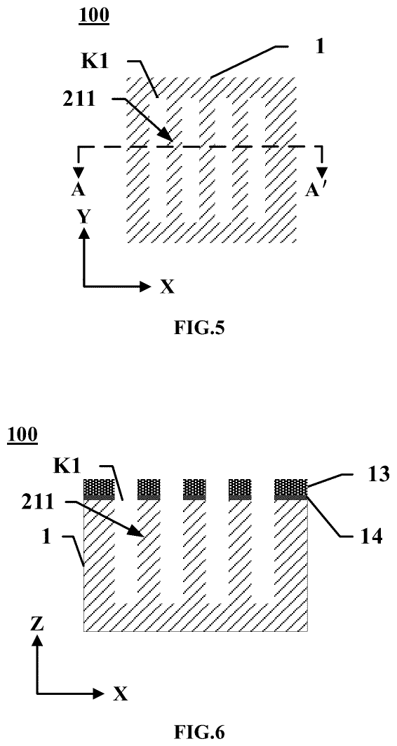

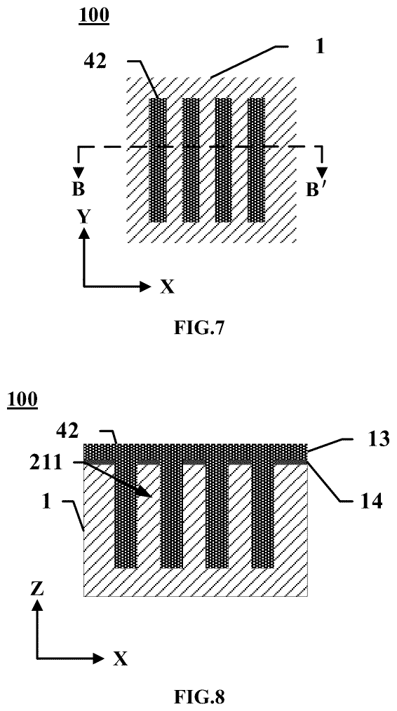

S120, forming a plurality of isolation trenches K1 extending along the second direction Y and arranged as being spaced apart along the first direction X in the substrate 1 as shown in FIGS. 5 and 6, and filling a dielectric material 42 at inner walls of the isolation trenches K1 as shown in FIGS. 7 and 8.

In some particular examples, the plurality of isolation trenches K1 may be formed in the substrate 1, or as shown in FIGS. 5 and 6, the plurality of isolation trenches K1 may be formed in the structure as shown in FIGS. 3 and 4. As shown in FIGS. 5 and 6, the plurality of isolation trenches K1 extend along the second direction Y and are arranged as being spaced apart along the first direction X, and the isolation trenches K1 extend along the third direction Z but do not penetrate through the substrate 1.

Forming the isolation trenches K1 comprises: etching from a surface of the second oxide layer 13 as shown in FIG. 4 to form the isolation trenches K1 extending along the second direction Y and arranged as being spaced apart along the first direction X, wherein the isolation trenches K1 may extend to the substrate 1 along the third direction Z but does not penetrate through the substrate 1. As shown in FIGS. 5 and 6, during the process of performing etching, part of regions (i.e., each region where the isolation trenches K1 need to be formed) of the surface of the substrate 1 or the second oxide layer 13 may be covered by a mask (not shown in the figures). Then, the surface of the substrate 1 is etched along a thickness direction (i.e., the third direction Z) of the substrate 1. A part of the substrate 1, the first dielectric layer 14 and the second oxide layer 13 outside the regions covered by the mask is etched off to form grooves with a certain depth, i.e., the above-mentioned isolation trenches K1. It is to be noted that, an etching depth to form the isolation trenches K1 is less than an initial thickness of the substrate 1, that is, the substrate 1 is not etched through by the etching process.

In some particular examples, the etching may be performed using processes such as photolithography (PH) or dry etching (ET), etc., for example, an electron beam lithography process, a plasma etching process or a reactive ion etching process, etc., on which some examples of the present application do not impose limitations.

In some examples of the present application, the plurality of isolation trenches K1 with the same depth are formed synchronously by etching the surface of the entire substrate 1, which can simplify the fabrication process and improve efficiency.

In some particular examples, FIG. 7 is a top view of depositing the dielectric material 42 in the isolation trenches K1 provided by some examples of the present application, and FIG. 8 is a cross-sectional view of depositing the dielectric material 42 in the isolation trenches K1 provided by some examples of the present application. After the formation of the isolation trenches K1 as shown in FIGS. 5 and 6, as shown in FIGS. 7 and 8, the dielectric material 42 is deposited in the isolation trenches K1 using a deposition process.

In some examples, the dielectric material 42 includes, but is not limited to, a combination of any one or more of silicon nitride, silicon oxide or silicon oxynitride. Here, silicon oxide refers to a silicon-oxygen compound, such as SixOy, and silicon nitride refers to a nitrogen-silicon compound, such as SixNy.

Since the isolation trenches K1 are formed as shown in FIGS. 5 and 6 and the plurality of isolation trenches K1 are arranged as being spaced apart along the first direction X, there will be a protrusion structure 211 for spacing apart two adjacent ones of the isolation trenches K1 between the isolation trenches K1 formed in the substrate 1 by removing part of the semiconductor material. It is to be noted that, during actual deposition of the dielectric material 42, the dielectric material 42 will cover a surface of the protrusion structure 211, and the dielectric material 42 is filled around each protrusion structure 211 as shown in FIG. 7. In addition, after the deposition is finished, the excess dielectric material 42 may be removed to achieve planarization by grinding using a chemical mechanical polishing (CMP) process.

In some examples of the present application, a deposition method of the dielectric material 42, the first dielectric layer 14 and the second oxide layer 13 may employ, but is not limited to, chemical vapor deposition (CVD), physical vapor deposition (PVD), plasma-enhanced CVD (PECVD), sputtering, metal-organic chemical vapor deposition (MOCVD) and atomic layer deposition (ALD), etc.

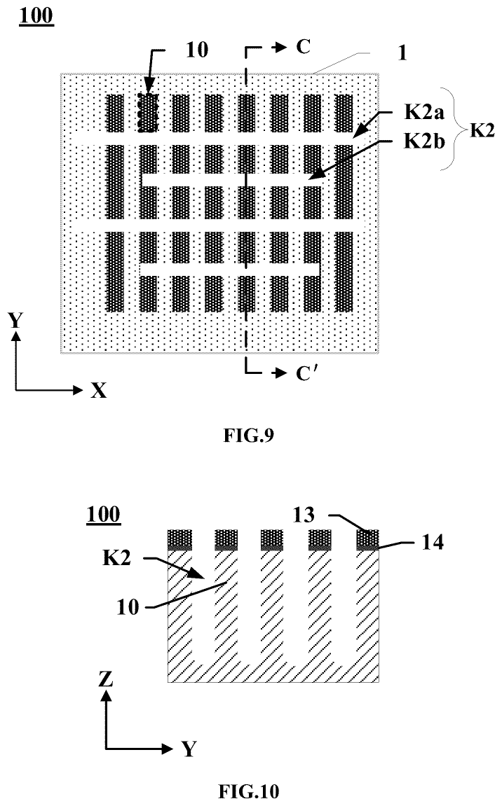

S130, forming a plurality of gate trenches K2 extending along the first direction X and arranged as being spaced apart along the second direction Y, to form the plurality of semiconductor pillars 10 extending along the first direction X and arranged as being spaced apart along the second direction Y and extending along the third direction Z, as shown in FIGS. 9 and 10.

In some particular examples, after the filling of the dielectric material 42 in the isolation trenches K1, as shown in FIGS. 9 and 10, the gate trenches K2 extending along the first direction X and arranged as being spaced apart along the second direction Y are formed in the substrate 1, and along the second direction Y, the semiconductor pillar 10 is located between adjacent ones of the gate trenches K2. The isolation trenches K1 filled with the dielectric material 42 extend along the second direction Y and are arranged as being spaced apart along the first direction X, while the gate trenches K2 extend along the first direction X and are arranged as being spaced apart along the second direction Y, so that the gate trenches K2 can divide the isolation trenches K1 filled with the dielectric material 42 into the plurality of semiconductor pillars 10 arranged in an array in the first direction X and the second direction Y and extending in the third direction Z.

In some particular examples, dimensions along the first direction X of the plurality of gate trenches K2 arranged as being spaced apart in the second direction Y may be either the same or different. For example, as shown in FIGS. 9 and 10, the gate trench K2a and the gate trench K2b are arranged as being staggered and spaced apart along the second direction Y, and the dimension of the gate trench K2a along the first direction X is greater than the dimension of the gate trench K2b along the first direction X.

In some particular examples, the dimension of the gate trench K2 formed by etching along the second direction Y is equal to the dimension of the semiconductor pillar 10 along the second direction Y.

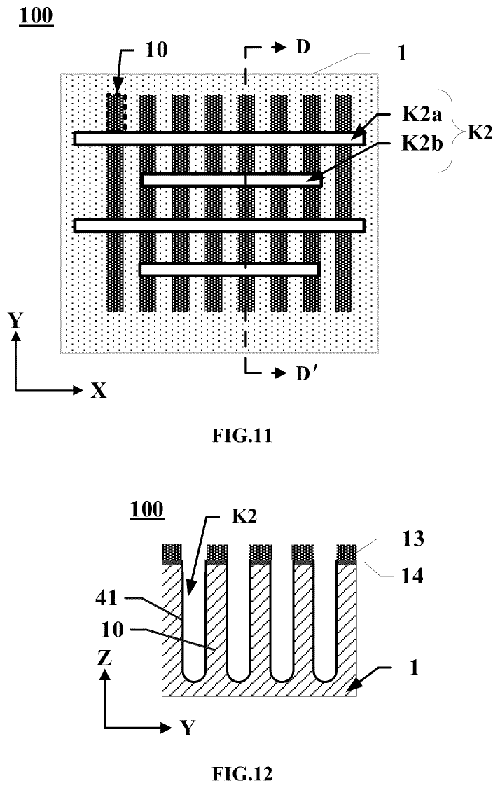

S200, forming one gate strip 30 and one shielding strip 20 between adjacent ones of the semiconductor pillars 10, wherein the gate strip 30 and the shielding strip 20 extend along the first direction X and are spaced apart in the second direction Y; and
in some examples, the forming one gate strip 30 and one shielding strip 20 comprises:
S210, forming a first oxide layer 41 within sidewalls of the gate trenches K2, as shown in FIGS. 11 and 12.

In some particular examples, as shown in FIGS. 9 and 10, after the formation of the gate trenches K2, the first oxide layer 41 may be formed within the sidewalls of the gate trenches K2 as shown in FIGS. 11 and 12, and the first oxide layer 41 may be a silicon oxide layer formed by rapid thermal oxidation (RTO) or in-situ stream generation (ISSG). As shown in FIGS. 11 and 12, oxidization treatment is performed on an exposed sidewall of the semiconductor pillar 10 through the gate trench K2, and the first oxide layer 41 is formed within the sidewall of the semiconductor pillar 10, i.e., the sidewall of the gate trench K2. A process for performing the oxidation treatment on the sidewall of the above-mentioned semiconductor pillar 10 exposed in the gate trench K2 includes, but is not limited to, direct oxidation, alkaline oxidation or acidic oxidation.

In some examples of the present application, silicon on the sidewall of the semiconductor pillar 10 chemically reacts with gas containing oxidation substances at a high temperature by direct oxidation through heating, such that a layer of dense silicon dioxide film is generated on the silicon surface, thereby forming the first oxide layer 41 on the sidewall of the semiconductor pillar 10. The first oxide layer 41 comprises an insulation material such as silicon oxide, silicon oxynitride, etc.

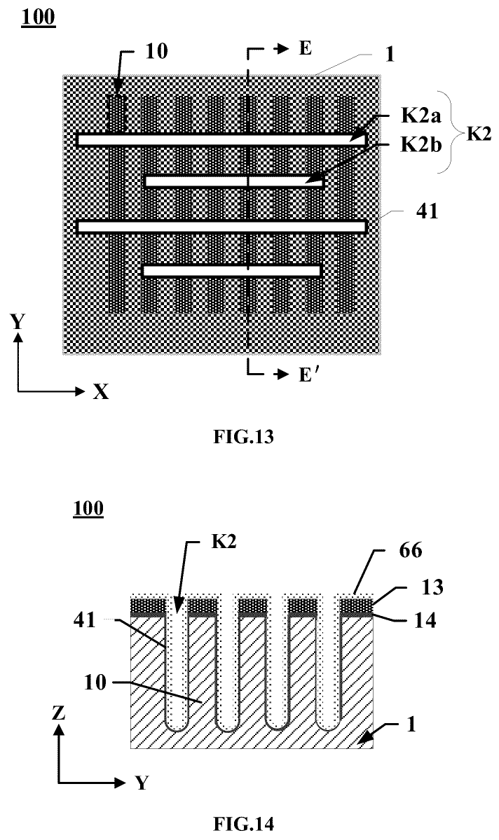

S220, forming a conductive layer 66 within a sidewall of the first oxide layer 41, as shown in FIGS. 13 and 14.

In some particular examples, the conductive layer 66 is formed within the sidewall of the first oxide layer 41 by deposition, and a material of the conductive layer includes, but is not limited to, a conductive material such as tungsten (W), cobalt (Co), copper (Cu), aluminum (Al), silicides or any combination thereof.

In some examples, a deposition method of the conductive material may employ, but is not limited to, chemical vapor deposition (CVD), physical vapor deposition (PVD), plasma-enhanced CVD (PECVD), sputtering, metal-organic chemical vapor deposition (MOCVD) and atomic layer deposition (ALD), etc.

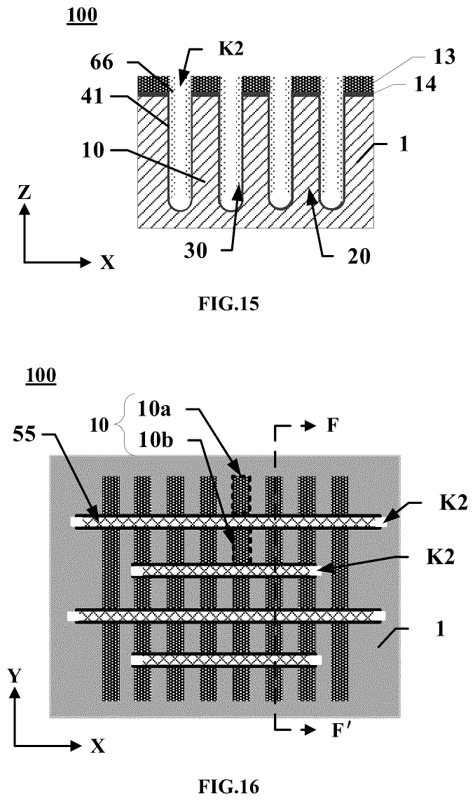

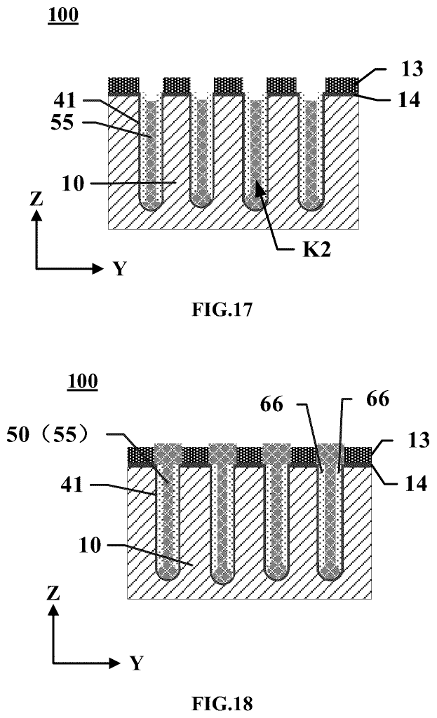

S230, removing part of the conductive layer 66 on the sidewall of the first oxide layer 41 and close to the substrate 1 along the third direction Z, and connection portions at two ends of the gate trench K2 in the first direction X, to form the gate strip 30 and the shielding strip 20 that are separated, as shown in FIGS. 15 and 16.

S300, forming a barrier strip 90 at an end of the shielding strip 20 along the third direction Z, wherein the barrier strip 90 extends along the first direction X and is located on the same side of the shielding strip 20 and the gate strip 30 in the third direction Z.

In some particular examples, the gate strip 30 and the shielding strip 20 formed in the gate trench K2 are adjacent in the second direction Y, and the gate strip 30 and the shielding strip 20 are each located on a side of the semiconductor pillar 10 adjacent thereto. For example, as shown in FIG. 28, the semiconductor pillar 10a and the semiconductor pillar 10b are adjacent in the second direction Y. The gate strip 30 and the shielding strip 20 are disposed between the semiconductor pillar 10a and the semiconductor pillar 10b, the gate strip 30 is located on a side close to the semiconductor pillar 10b along the second direction Y, and the shielding strip 20 is located on a side close to the semiconductor pillar 10a along the second direction Y.

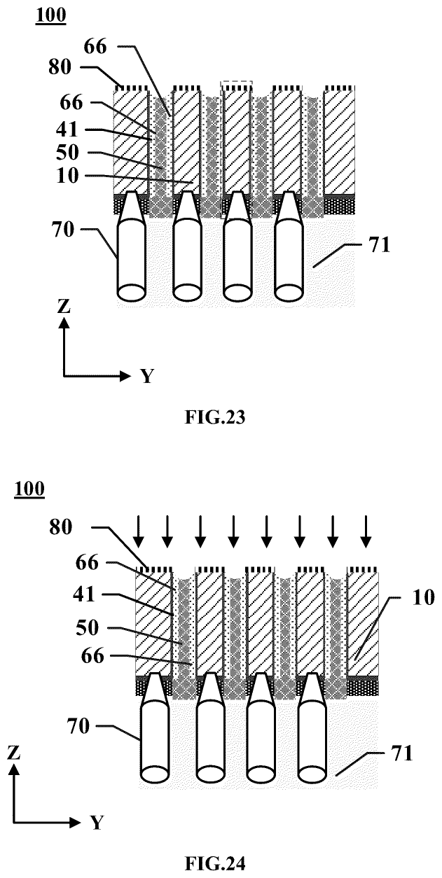

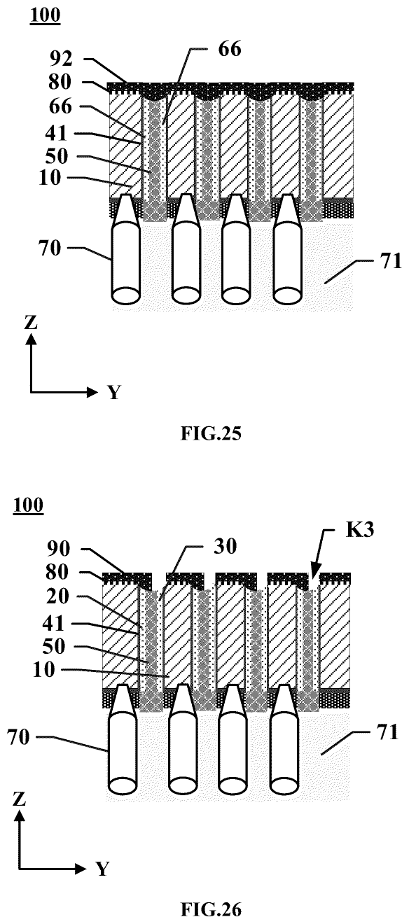

Forming the barrier strip 90 comprises: depositing an isolation layer 80 at an end of the semiconductor pillar 10 facing away from the capacitor array 71 along the third direction Z as shown in FIG. 23, and doping (e.g., N-type doping that may comprise any suitable dopants, e.g., an N-type dopant, such as phosphorus (P), arsenic (Ar) or antimony (Sb)) the exposed gate strip 30 and the shielding strip 20 by, for example, an ion implantation process (an IMP process) or other processes as shown in FIG. 24, to contribute free electrons and improve electrical conductivity of the gate strip 30 and the shielding strip 20. As shown in FIG. 25, a barrier layer 92 covering the semiconductor pillar 10, the gate strip 30 and the shielding strip 20 is formed based on a deposition process, and extends along the second direction Y. Part of the barrier layer 92 connected with the shielding strip 20 as shown in FIG. 25 is removed to form a groove K3 as shown in FIG. 26, such that the remaining barrier layer 92 after the part of the barrier layer 92 connected with the shielding strip 20 is removed forms the barrier strip 90 extending along the first direction X as shown in FIG. 26. In the third direction Z, the barrier strip 90 is connected with an end of the shielding strip 20, and the barrier strip 90 is located at the same end of the shielding strip 20 in the third direction Z as the gate strip 30.

In some examples of the present application, the two electrodes, i.e., the first electrode and the second electrode, are formed between adjacent ones of the semiconductor pillars 10, and the barrier strip 90 extending along the first direction X and connected with the second electrode is formed at the same end of the first electrode and the second electrode in the third direction Z. As such, the first electrode can serve as the gate strip 30, and the second electrode can serve as the shielding strip 20. The shielding strip 20 may be formed by the barrier strip 90 at the same time as forming the gate strip 30, such that the interference of the gate strip 30 to the adjacent semiconductor pillar 10 can be shielded, thus reducing the coupling effect between adjacent ones of the semiconductor pillars 10.

In some examples, the fabrication method further comprises: filling an isolation material 55 in the gate trench K2, wherein the isolation material 55 covers the gate strip 30 and the shielding strip 20 to form the isolation structure 50, as shown in FIGS. 15, 17 and 18.

In some particular examples, a material of the isolation material 55 includes, but is not limited to, a combination of any one or more of silicon nitride, silicon oxide or silicon oxynitride. A deposition method of the isolation material 55 may employ, but is not limited to, chemical vapor deposition (CVD), physical vapor deposition (PVD), plasma-enhanced CVD (PECVD), sputtering, metal-organic chemical vapor deposition (MOCVD) and atomic layer deposition (ALD), etc.

In some examples, the fabrication method further comprises:
forming a capacitor array 71 at the other end of the semiconductor pillar array in the third direction Z as shown in FIG. 19, wherein the capacitor array 71 comprises a plurality of capacitor structures 70 arranged in an array along the first direction X and the second direction Y and extending in the third direction Z, and the capacitor structures 70 each comprises a first electrode layer (not shown in the figures) connected with the other end of the semiconductor pillar 10 in the third direction Z, and a capacitor dielectric layer (not shown in the figures) and a second electrode layer (not shown in the figures) within the first electrode layer.

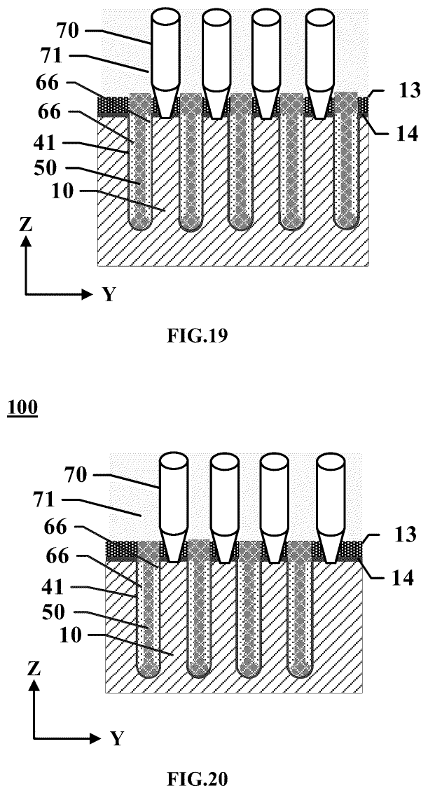

In some particular examples, as shown in FIG. 19, the capacitor array 71 is formed at the other end of the semiconductor pillar array in the third direction Z, and a part of the substrate 1 away from the capacitor array 71 along the third direction Z is removed as shown in FIG. 20.

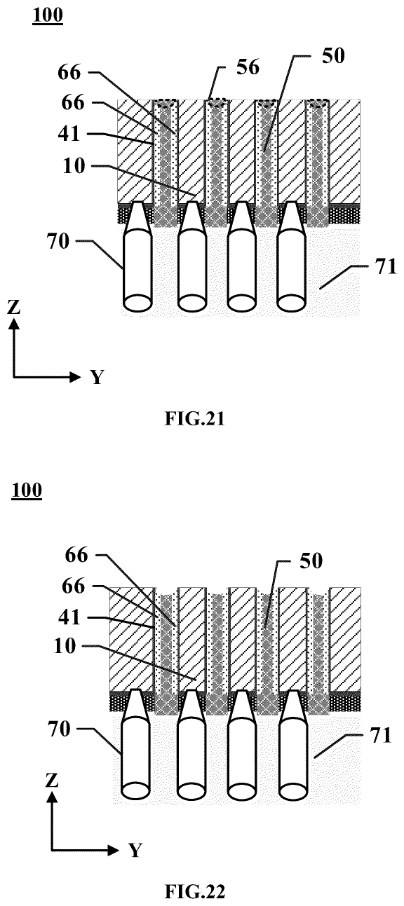

In some examples, the fabrication method further comprises:
removing an end of the substrate 1 away from the capacitor array 71 in the third direction Z, and the isolation structure 50 at the bottom of the gate trench K2, to expose an end of the gate strip 30 in the third direction Z and an end of the shielding strip 20 in the third direction Z, as shown in FIGS. 21 and 22.

In some particular examples, as shown in FIG. 21, the end of the substrate 1 away from the capacitor array 71 in the third direction Z may be removed by processes such as photolithography (PH) or dry etching (ET), etc. Then, as shown in FIG. 22, part of the isolation material 55 in the isolation structure 50 away from the capacitor array 71 along the third direction Z, i.e., a bottom end portion 56 of the isolation structure 50, may be removed using dry etching or wet etching. The bottom end portion 56 of the isolation structure 50 covers an end of the gate strip 30 away from the capacitor array 71 and covers an end of the shielding strip 20 away from the capacitor array 71 in the third direction Z. Thus, by removing the bottom end portion 56 of the isolation structure 50, the end of the gate strip 30 in the third direction Z and the end of the shielding strip 20 in the third direction Z may be exposed.

In some examples, the fabrication method further comprises:
forming a gate conductive connection structure 31 at the bottom of the gate trench K2, wherein the gate conductive connection structure 31 extends along the first direction X, and is located at an end of the gate strip 30 and the isolation structure 50 in the third direction Z, and is spaced apart from the end of the shielding strip 20 in the third direction Z.

In some particular examples, the groove K3 is located at ends of the gate strip 30 and the isolation structure 50 away from the capacitor structure 70 in the third direction Z, and the groove K3 is spaced apart from an end of the shielding strip 20 away from the capacitor structure 70 in the third direction Z. As such, the gate conductive connection structure 31 is formed within the groove K3 as shown in FIG. 26, and the gate conductive connection structure 31 as shown in FIG. 28 may be formed. A material of the gate conductive connection structure 31 may be referred to the above examples, which is no longer repeated here.

In some examples, the fabrication method further comprises:
forming a gate lead-out contact 32 at an end of the semiconductor pillar array in the third direction Z as shown in FIGS. 26 to 28, wherein the gate lead-out contact 32 is connected with the gate conductive connection structure 31.

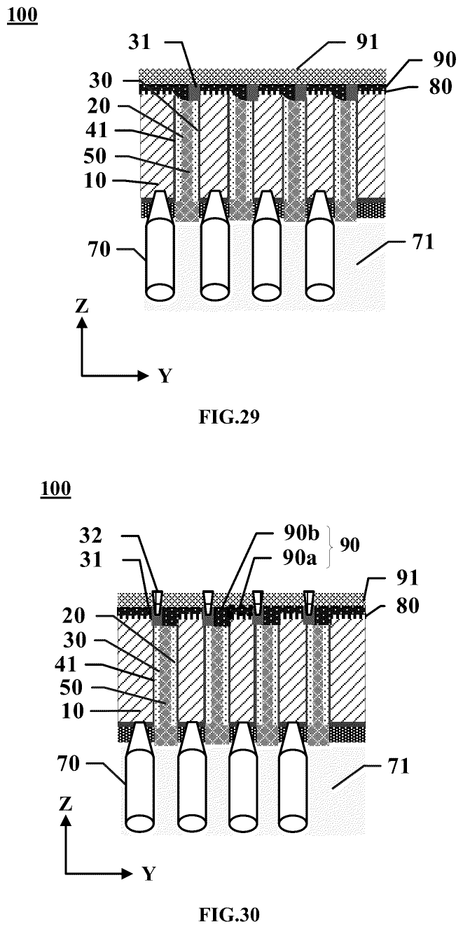

In some particular examples, as shown in FIG. 29, an insulation layer 91 is deposited at an end of the semiconductor pillar array away from the capacitor array 71 in the third direction Z, and the insulation layer 91 covers the barrier strip 90 and the gate conductive connection structure 31. A part of the insulation layer 91 is removed to form a first trench K4, and the gate lead-out contact 32 is formed in the first trench K4. A material of the gate lead-out contact 32 may be referred to the above examples, which is no longer repeated here.

In some examples, the fabrication method further comprises:
forming a shielding lead-out contact 21 at the end of the semiconductor pillar array in the third direction Z as shown in FIGS. 31 to 32 or as shown in FIGS. 33, 34 and 36, wherein the shielding lead-out contact 21 is connected with the shielding strip 20. A part of the insulation layer 91 is removed to form a second trench K5, and the shielding lead-out contact 21 is formed in the second trench K5. A material of the shielding lead-out contact 21 may be referred to the above examples, which is no longer repeated here.

In some examples, the fabrication method further comprises:
forming a semiconductor pillar lead-out contact 11 at the end of the semiconductor pillar array in the third direction Z as shown in FIGS. 35 and 36, wherein the semiconductor pillar lead-out contact 11 is connected with the semiconductor pillar 10. A part of the insulation layer 91 is removed to form a third trench K6, and the semiconductor pillar lead-out contact 11 is formed in the third trench K6. A material of the semiconductor pillar lead-out contact 11 may be referred to the above examples, which is no longer repeated here.

As shown in FIGS. 26 to 29 and 33 to 34, in some examples, the forming the gate lead-out contact 32 at the end of the semiconductor pillar array in the third direction Z comprises:
forming a plurality of the gate lead-out contacts 32, wherein one of the gate lead-out contacts 32 corresponds to one gate conductive connection structure 31, and the plurality of gate lead-out contacts 32 are synchronously arranged as being spaced apart along the first direction X and the second direction Y in a staircase distribution.

As shown in FIGS. 26 to 29 and 33 to 34, in some examples, the forming the shielding lead-out contact 21 at the end of the semiconductor pillar array in the third direction Z comprises:
forming a plurality of the shielding lead-out contacts 21, wherein one of the shielding lead-out contacts 21 corresponds to one shielding strip 20, and the plurality of shielding lead-out contacts 21 are synchronously arranged as being spaced apart along the first direction X and the second direction Y in a staircase distribution.

As shown in FIGS. 26 to 29 and 33 to 34, in some examples, the fabrication method further comprises forming a plurality of gate lead-out contacts 32 and a plurality of shielding lead-out contacts 21, wherein one of the gate lead-out contacts 32 corresponds to one gate conductive connection structure 31, one of the shielding lead-out contacts 21 corresponds to one shielding strip 20, and the plurality of gate lead-out contacts 32 and the plurality of shielding lead-out contacts 21 are synchronously arranged as being staggered and spaced apart along the first direction X and the second direction Y in a staircase distribution.

As shown in FIGS. 31 to 32, in some examples, the fabrication method further comprises forming the plurality of gate lead-out contacts and the plurality of shielding lead-out contacts, wherein one of the gate lead-out contacts corresponds to one gate conductive connection structure, one of the shielding lead-out contacts corresponds to one shielding strip, and the plurality of gate lead-out contacts and the plurality of shielding lead-out contacts are synchronously arranged as being staggered and spaced apart along the first direction and the second direction.

In some examples, as shown in FIG. 32, the forming the plurality of semiconductor pillars 10 comprises making a difference between a cross-sectional dimension of the semiconductor pillars 10 in the second direction Y and a spacing dimension between two adjacent ones of the semiconductor pillars 10 be less than a preset value.

In some particular examples, before forming the first trench K4 for forming the gate lead-out contact 32 and the second trench K3 for forming the shielding lead-out contact 21 as shown in FIG. 33, a patterned first mask layer (not shown in the figure) is formed on a surface of the insulation layer 91 facing away from the capacitor array 71 along the third direction Z, wherein the first mask layer has a plurality of first openings (not shown in the figure) and second openings (not shown in the figure). The first opening is used to form the first trench K4, and the second opening is used to form the second trench K5. The openings corresponding to the first trench K4 and the second trench K5 are formed in the patterned first mask layer, and expose positions of the first trench K4 and the second trench K5 to be etched by an etching process performed subsequently. That is, along the third direction Z, a vertical projection of the first opening on the surface of the insulation layer 91 facing away from the capacitor array 71 may at least substantially overlap the position of the first trench K4; and along the third direction Z, a vertical projection of the second opening on the surface of the insulation layer 91 facing away from the capacitor array 71 may at least substantially overlap the position of the second trench K5. By disposing the first mask layer, the etching positions of the first trench K4 and the second trench K5 can be determined quickly and accurately to facilitate etching processing on the insulation layer 91, and then the gate lead-out contact 32 is formed within the first trench K4, and the shielding lead-out contact 21 is formed within the second trench K5.

In some particular examples, before forming the third trench K6 for forming the semiconductor pillar lead-out contact 11 as shown in FIG. 34, a patterned second mask layer (not shown in the figure) is formed on the surface of the insulation layer 91 facing away from the capacitor array 71 along the third direction Z, and the second mask layer has a plurality of third openings (not shown in the figure) which are configured to form the third trench K6. The opening corresponding to the third trench K6 is formed in the patterned second mask layer, and exposes a position of the third trench K6 to be etched by an etching process performed subsequently, i.e., along the third direction Z, a vertical projection of the third opening on the surface of the insulation layer 91 facing away from the capacitor array 71 may at least substantially overlap the position of the third trench K6. By disposing the second mask layer, the etching position of the third trench K6 can be determined quickly and accurately to facilitate etching processing for the insulation layer 91 to form the third trench K6, and then the semiconductor pillar lead-out contact 11 is formed within the third trench K6.

The semiconductor device 100 and the fabrication method thereof are provided by some examples of the present application. A shielding strip 20 is further formed between adjacent ones of the semiconductor pillars 10 in the semiconductor device 100 formed by the fabrication method, and the shielding strip 20 can avoid the interference between adjacent ones of the semiconductor pillars 10, thus reducing the coupling effect between adjacent ones of the semiconductor pillars 10.

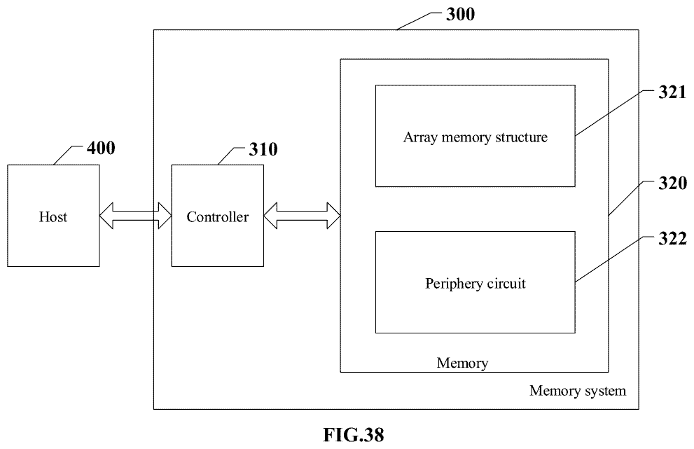

Based on the above-mentioned semiconductor device 100 and the fabrication method thereof, with reference to FIG. 38, examples of the present application further provide a memory 320, which comprises:
an array memory structure 321 comprising the semiconductor device 100 of the examples as shown in FIGS. 3 to 36; and a periphery circuit 322 that is connected with the array memory structure 321 to control a bias voltage of the array memory structure 321.

Based on the above-mentioned semiconductor device 100 and the fabrication method thereof, referring to FIG. 38, examples of the present application further provide a memory system 300 which comprises the memory 320 as shown in FIG. 38, and a controller coupled with the memory 320, wherein the controller is configured to control the memory to perform data write and read operations.

In an example, as shown in FIG. 38, the memory system 300 comprises the controller 310 and one or more memories 320, wherein the memory 320 (3D NAND Flash) comprises an array memory structure 321 and a periphery circuit 322, and wherein the array memory structure 321 comprises the semiconductor device 100 of any one of the above examples. The memory system 300 may communicate with a host 400 through the controller 310, wherein the controller 310 may be connected to the one or more memories 320 via channels in the one or more memories 320. Each memory 320 may be managed by the controller 310 via the channel in the memory 320.

In an example, the array memory structure 321 is configured to store information, and the periphery circuit 322 may be located above or below the array memory structure 321, and may be also located around the array memory structure 321. The periphery circuit 322 is configured to control the corresponding array memory structure 321. In addition, the semiconductor device 100 may be further applied in other microelectronic devices, such as a Nor Flash, etc., which is not limited specifically. In addition, the semiconductor device 100 of the examples of the present application may be the memory 320, and may be a part of a periphery memory, which is not limited particularly.

A semiconductor device 100 and a fabrication method thereof, a memory and a memory system 300 provided by the examples of the present application are introduced above in detail. The principle and implementations of the present application are set forth herein by applying specific cases. The descriptions of the above examples are only to help understand the methods and core ideas of the present application. Meanwhile, those skilled in the art may make changes over the specific implementations and application scope according to the ideas of the present application. To sum up, the contents of this specification should not be interpreted as limitations to the present application.

What is claimed is:

1. A semiconductor device, comprising:
a semiconductor pillar array comprising a plurality of semiconductor pillars arranged in an array along a first direction and a second direction and extending in a third direction, wherein the first direction, the second direction and the third direction intersect with each other;
a gate strip and a shielding strip disposed between adjacent ones of the semiconductor pillars along the second direction, wherein the gate strip and the shielding strip extend along the first direction and are spaced apart in the second direction; and
a barrier strip extending along the first direction, wherein the barrier strip is connected with an end of the shielding strip in the third direction, and is located on a same side of the shielding strip and the gate strip in the third direction.

2. The semiconductor device of claim 1, further comprising:
a gate conductive connection structure, wherein the gate conductive connection structure extends along the first direction, and is located between an end of the gate strip in the third direction and the barrier strip, and is at least partially in juxtaposition to the barrier strip; and
a gate lead-out contact at an end of the semiconductor pillar array in the third direction, wherein the gate lead-out contact is connected with the gate conductive connection structure.

3. The semiconductor device of claim 2, further comprising: a shielding lead-out contact at the end of the semiconductor pillar array in the third direction, wherein the shielding lead-out contact is connected with the shielding strip.

4. The semiconductor device of claim 1, comprising:
a plurality of gate strips arranged as being spaced apart between rows of the semiconductor pillars along the second direction;
a plurality of shielding strips arranged as being spaced apart between the rows of the semiconductor pillars along the second direction and arranged as being staggered and spaced apart with the plurality of gate strips;
a plurality of barrier strips arranged as being spaced apart between the rows of the semiconductor pillars along the second direction; and
a plurality of gate conductive connection structures arranged as being spaced apart between the rows of the semiconductor pillars along the second direction.

5. The semiconductor device of claim 4, further comprising: a plurality of gate lead-out contacts, wherein one of the gate lead-out contacts corresponds to one of the gate conductive connection structures, and the plurality of gate lead-out contacts are synchronously arranged as being spaced apart along the first direction and the second direction in a staircase distribution.

6. The semiconductor device of claim 4, further comprising: a plurality of shielding lead-out contacts, wherein one of the shielding lead-out contacts corresponds to one of the shielding strips, and the plurality of shielding lead-out contacts are synchronously arranged as being spaced apart along the first direction and the second direction in a staircase distribution.

7. The semiconductor device of claim 4, further comprising a plurality of gate lead-out contacts and a plurality of shielding lead-out contacts, wherein one of the gate lead-out contacts corresponds to one of the gate conductive connection structures, one of the shielding lead-out contacts corresponds to one of the shielding strips, and the plurality of gate lead-out contacts and the plurality of shielding lead-out contacts are synchronously arranged as being staggered and spaced apart along the first direction and the second direction in a staircase distribution.

8. The semiconductor device of claim 4, further comprising a plurality of gate lead-out contacts and a plurality of shielding lead-out contacts, wherein one of the gate lead-out contacts corresponds to one of the gate conductive connection structures, one of the shielding lead-out contacts corresponds to one of the shielding strips, and the plurality of gate lead-out contacts and the plurality of shielding lead-out contacts are arranged as being staggered and spaced apart along the second direction.

9. The semiconductor device of claim 1, wherein a cross-sectional dimension of the semiconductor pillars in the second direction is equal to a spacing dimension between two adjacent ones of the semiconductor pillars.

10. The semiconductor device of claim 1, further comprising:
a first oxide layer between the semiconductor pillar and the gate strip and between the semiconductor pillar and the shielding strip; and
an isolation structure between the gate strip and the shielding strip.

11. The semiconductor device of claim 1, further comprising: a capacitor array at an end of the semiconductor pillar array in the third direction,
wherein the capacitor array comprises a plurality of capacitor structures arranged in an array along the first direction and the second direction and extending in the third direction, and the capacitor structures comprise a first electrode layer connected with an end of the semiconductor pillar in the third direction, and a capacitor dielectric layer and a second electrode layer within the first electrode layer.

12. A method of forming a semiconductor device, the method comprising:
forming a semiconductor pillar array comprising a plurality of semiconductor pillars that are arranged in an array along a first direction and a second direction and extend in a third direction, wherein the first direction, the second direction and the third direction intersect with each other, and the semiconductor pillar array comprises a first end and a second end opposite to the first end;
forming a gate strip and a shielding strip between adjacent ones of the semiconductor pillars, wherein the gate strip and the shielding strip extend along the first direction and are spaced apart in the second direction; and
forming a barrier strip at an end of the shielding strip along the third direction, wherein the barrier strip extends along the first direction, and is located on a same side of the shielding strip and the gate strip in the third direction.

13. The method of claim 12, wherein forming the plurality of semiconductor pillars comprises:
providing a substrate;
forming a plurality of isolation trenches extending along the second direction and arranged as being spaced apart along the first direction in the substrate, and filling a dielectric material at inner walls of the isolation trenches; and
forming a plurality of gate trenches extending along the first direction and arranged as being spaced apart along the second direction, to form the plurality of semiconductor pillars extending along the first direction and arranged as being spaced apart along the second direction and extending in the third direction.

14. The method of claim 13, wherein forming the gate strip and the shielding strip comprises:
forming a first oxide layer within sidewalls of the gate trenches;
forming a conductive layer within sidewalls of the first oxide layer; and
removing part of the conductive layer on the sidewalls of the first oxide layer and close to the substrate along the third direction, and connection portions at two ends of the gate trenches in the first direction, to form the gate strip and the shielding strip that are separated.

15. The method of claim 14, further comprising: filling an isolation material in the gate trenches, and making the isolation material cover the gate strip and the shielding strip to form an isolation structure.

16. The method of claim 15, further comprising:
forming a capacitor array at the second end of the semiconductor pillar array in the third direction, wherein the capacitor array comprises a plurality of capacitor structures arranged in an array along the first direction and the second direction and extending in the third direction, and the capacitor structures comprise a first electrode layer connected with an end of the semiconductor pillar in the third direction, and a capacitor dielectric layer and a second electrode layer within the first electrode layer.

17. The method of claim 16, further comprising:
removing an end of the substrate away from the capacitor array in the third direction, and the isolation structure at a bottom of each of the gate trenches, to expose an end of the gate strip in the third direction and an end of the shielding strip in the third direction;
forming a gate conductive connection structure at the bottom of each of the gate trenches, wherein the gate conductive connection structure extends along the first direction, and is located at an end of the gate strip and the isolation structure in the third direction, and is spaced apart from the end of the shielding strip in the third direction; and
forming a gate lead-out contact at the first end of the semiconductor pillar array in the third direction, wherein the gate lead-out contact is connected with the gate conductive connection structure.

18. The method of claim 17, wherein forming the gate lead-out contact at the first end of the semiconductor pillar array in the third direction comprises:
forming a plurality of the gate lead-out contacts, wherein one of the gate lead-out contacts corresponds a corresponding gate conductive connection structure, and the plurality of gate lead-out contacts are synchronously arranged as being spaced apart along the first direction and the second direction in a staircase distribution.

19. The method of claim 14, further comprising:
forming a shielding lead-out contact at the first end of the semiconductor pillar array in the third direction, wherein the shielding lead-out contact is connected with the shielding strip.

20. A memory system, comprising:
a semiconductor device comprising:
a semiconductor pillar array comprising a plurality of semiconductor pillars arranged in an array along a first direction and a second direction and extending in a third direction, wherein the first direction, the second direction and the third direction intersect with each other;
a gate strip and a shielding strip disposed between adjacent ones of the semiconductor pillars along the second direction, wherein the gate strip and the shielding strip extend along the first direction and are spaced apart in the second direction; and
a barrier strip extending along the first direction, wherein the barrier strip is connected with an end of the shielding strip in the third direction, and is located on the same side of the shielding strip and the gate strip in the third direction; and
a controller coupled with the semiconductor device, wherein the controller is configured to control the semiconductor device to perform data write and read operations.
